(19) United States
(12) Patent Application Publication
(10) Pub. No.: US 2017/0229609 A1
(43) Pub. Date: Aug. 10, 2017

(54) NITRIDE SEMICONDUCTOR LIGHT-EMITTING ELEMENT

(71) Applicant: NICHIA CORPORATION, Anan-shi (JP)

(72) Inventor: Atsuo MICHIUE, Anan-shi (JP)

(73) Assignee: NICHIA CORPORATION, Anan-shi (JP)

(21) Appl. No.: 15/426,800

(22) Filed: Feb. 7, 2017

(30) Foreign Application Priority Data
Feb. 9, 2016 (JP) 2016-022978

(51) Int. Cl. H01L 33/06; H01L 33/12; H01L 33/32

(52) U.S. Cl. CPC H01L 33/06; H01L 33/32; H01L 33/12

(57) ABSTRACT

A nitride semiconductor light-emitting element includes an n-side layer; a p-side layer; and a light-emitting layer having a multiple quantum well structure, the light-emitting layer being located between the n-side layer and the p-side layer. The light-emitting layer includes: an n-side first barrier layer, a plurality of well layers, including an n-side first well layer, an n-side second well layer, and one or more additional well layers, and a plurality of intermediate layers, including an n-side first intermediate barrier layer and one or more additional intermediate barrier layers. A band gap of the n-side first intermediate barrier layer is smaller than a band gap of the n-side first barrier layer. A band gap of each of the one or more additional intermediate barrier layers is larger than a band gap of the n-side first intermediate barrier layer.

### CROSS-REFERENCE TO RELATED APPLICATION

This application claims priority to Japanese Patent Application No. 2016-022978 filed on Feb. 9, 2016, which is hereby incorporated herein by reference in its entirety.

### BACKGROUND

The present disclosure relates to nitride semiconductor light-emitting elements.

Light-emitting elements formed using nitride semiconductors (nitride semiconductor light-emitting elements) have been widely used in recent years. A nitride semiconductor light-emitting element includes, for example, an n-type nitride semiconductor layer, a light-emitting layer, and a p-type nitride semiconductor layer laminated over a substrate in this order, thereby emitting light with a predetermined wavelength. In general, a semiconductor light-emitting element is expected to be capable of enhancing the luminous efficiency by forming a light-emitting layer with a quantum well structure. For this reason, a nitride semiconductor light-emitting element including a light-emitting layer with a quantum well structure has been variously studied for the purpose of further improving the luminous efficiency.

For example, JP 2008-311658 A discloses a nitride semiconductor light-emitting element that includes, in an active region, an intermediate barrier layer with a band gap that is relatively wider compared with other barrier layers, thereby making it possible to provide a light-emitting diode with improved luminous efficiency.

The nitride semiconductor has a high dislocation density, compared to other compound semiconductors, such as GaAs. By decreasing the dislocation density in the semiconductor, the nitride semiconductor light-emitting element can have the tendency to decrease the degree of reduction in the output at a high temperature. For this reason, a technique for forming a nitride semiconductor with a low dislocation density has been developed and made certain achievements.

### SUMMARY

The present inventors have found a problem with the nitride semiconductor light-emitting element descried above. Specifically, in the nitride semiconductor light-emitting element, the forward voltage for obtaining a predetermined current is disadvantageously increased as the dislocation density of the nitride semiconductor decreases. This is considered to be due to the influence of a piezoelectric field. In other words, as the number of dislocations decreases, the influence of the piezoelectric field is strengthened, thus worsening the uniformity of carrier distribution in a light-emitting layer, leading to the reduced probability of recombination between the electrode and hole.

Accordingly, it is an object of embodiments of the present invention to provide a nitride semiconductor light-emitting element that can decrease the forward voltage and improve the luminous efficiency.

To achieve the above-mentioned object, a nitride semiconductor light-emitting element according to one aspect of the present invention comprises: an n-side layer; a p-side layer; and alight-emitting layer having a multiple quantum well structure, the light-emitting layer being located between the n-side layer and the p-side layer. The light-emitting layer includes: an n-side first barrier layer, a plurality of well layers, including an n-side first well layer, an n-side second well layer, and one or more additional well layers, and a plurality of intermediate layers, including an n-side first intermediate barrier layer and one or more additional intermediate barrier layers. The layers of the light-emitting layer are disposed in the following order from a side of the n-side layer: the n-side first barrier layer, the n-side first well layer, the n-side first intermediate barrier layer, the n-side second well layer, a first additional intermediate barrier layer among the one or more additional intermediate barrier layers, and a first additional well layer among the one or more additional well layers. A band gap of the n-side first intermediate barrier layer is smaller than a band gap of the n-side first barrier layer. A band gap of each of the one or more additional intermediate barrier layers is larger than a band gap of the n-side first intermediate barrier layer.

The nitride semiconductor light-emitting element with the structure mentioned above can decrease the forward voltage and improve the luminous efficiency.

### BRIEF DESCRIPTION OF THE DRAWINGS

FIG. 1 is a cross-sectional view showing the structure of a nitride semiconductor light-emitting element according to a first embodiment.

FIG. 2A is a cross-sectional view showing the structure of a light-emitting layer in the nitride semiconductor light-emitting element according to the first embodiment.

FIG. 2B is a schematic diagram showing a band structure of the light-emitting layer in the nitride semiconductor light-emitting element according to the first embodiment.

FIG. 3A is a cross-sectional view showing the structure of a light-emitting layer in a nitride semiconductor light-emitting element according to a second embodiment.

FIG. 3B is a schematic diagram showing a band structure of the light-emitting layer in the nitride semiconductor light-emitting element according to the second embodiment.

FIG. 4A is a cross-sectional view showing the structure of a light-emitting layer in a nitride semiconductor light-emitting element according to a third embodiment.

FIG. 4B is a schematic diagram showing a band structure of the light-emitting layer in the nitride semiconductor light-emitting element according to the third embodiment.

FIG. 5A is a cross-sectional view showing the structure of a light-emitting layer in a nitride semiconductor light-emitting element according to a fourth embodiment.

FIG. 5B is a schematic diagram showing a band structure of the light-emitting layer in the nitride semiconductor light-emitting element according to the fourth embodiment.

FIG. 6A is a cross-sectional view showing the structure of a light-emitting layer in a nitride semiconductor light-emitting element according to a fifth embodiment.

FIG. 6B is a schematic diagram showing a band structure of the light-emitting layer in the nitride semiconductor light-emitting element according to the fifth embodiment.

FIG. 7A is a cross-sectional view showing the structure of a light-emitting layer in a nitride semiconductor light-emitting element according to a sixth embodiment.

FIG. 7B is a schematic diagram showing a band structure of the light-emitting layer in the nitride semiconductor light-emitting element according to the sixth embodiment.

FIG. 8A is a cross-sectional view showing the structure of a light-emitting layer in a nitride semiconductor light-emitting element according to a seventh embodiment.

FIG. 8B is a schematic diagram showing a band structure of the light-emitting layer in the nitride semiconductor light-emitting element according to the seventh embodiment.

FIG. 9A is a cross-sectional view showing the structure of a light-emitting layer in a nitride semiconductor light-emitting element according to an eighth embodiment.

FIG. 9B is a schematic diagram showing a band structure of the light-emitting layer in the nitride semiconductor light-emitting element according to the eighth embodiment.

FIG. 10 is a graph showing evaluation results of a slope efficiency (light output (a.u.)/current (mA)) of a nitride semiconductor light-emitting element in each of Examples 1 and 2.

FIG. 11 is a graph showing evaluation results of a forward voltage Vf of the nitride semiconductor light-emitting element in each of Examples 1 and 2.

### DETAILED DESCRIPTION OF EMBODIMENTS

Nitride semiconductor light-emitting elements according to embodiments of the present invention will be described below with reference to the accompanying drawings.

### First Embodiment

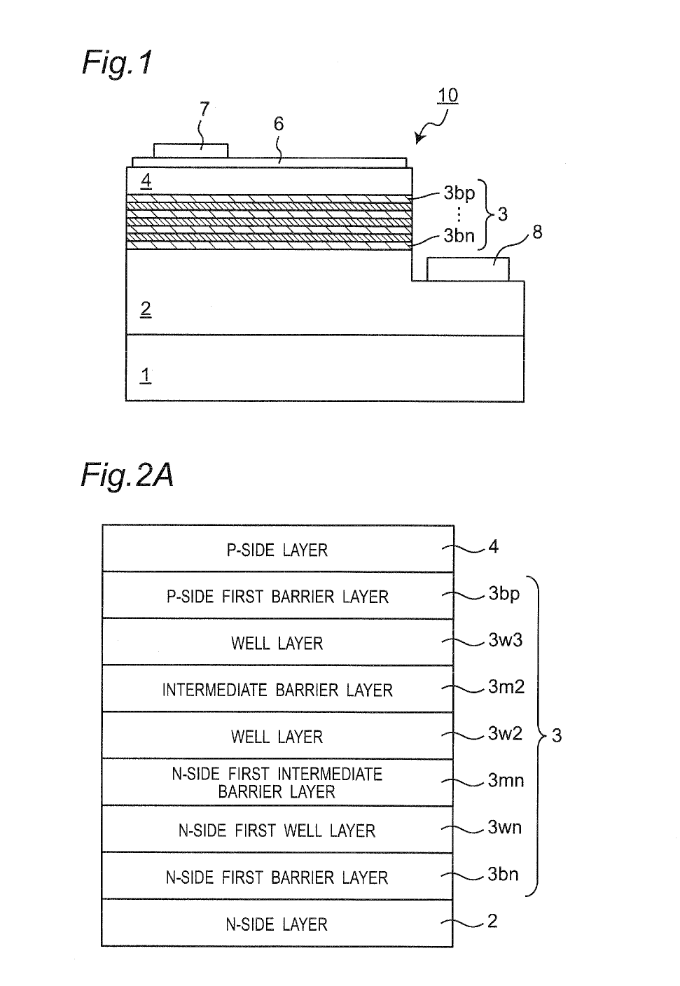

As shown in FIG. 1, a nitride semiconductor light-emitting element 10 in a first embodiment includes: a substrate 1; and an n-side layer (n-side semiconductor layer) 2, a light-emitting layer 3, and a p-side layer (p-side semiconductor layer) 4, which are provided over the substrate 1. Note that, for example, the substrate 1 may be removed after forming an n-side layer 2, the light-emitting layer 3, and the p-side layer 4. The n-side layer 2 includes an n-type contact layer, while the p-side layer 4 includes a p-type contact layer.

In the nitride semiconductor light-emitting element 10, an overall electrode 6 (first p electrode) is formed over the substantially entire upper surface of the p-side layer 4, and a pad electrode 7 (second p electrode) is formed over part of the overall electrode 6. The overall electrode 6 is in contact with a p-type contact layer that is part of the p-side layer 4. Parts of the p-side layer 4 and light-emitting layer 3 and a part of the n-side layer 2 are removed to expose an n-type contact layer, on an exposed surface of which an n-type electrode 8 is provided. The n-side layer 2, the light-emitting layer, 3 and the p-side layer 4 are made of a nitride semiconductor that is represented, for example, by formula of InₓAl_{y}Ga_{1-x-y}N (0≦x≦1, 0≦y≦1, 0≦x+y≦1).

### (Light-Emitting Layer in First Embodiment)

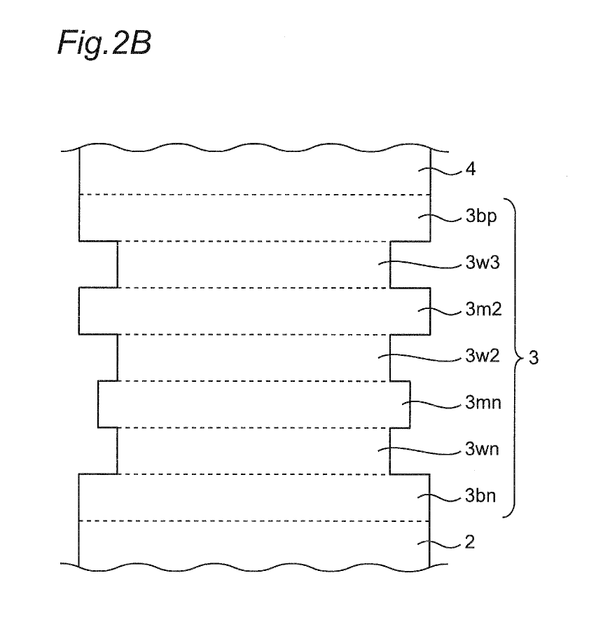

In the nitride semiconductor light-emitting element 10, as shown in FIG. 2A, the light-emitting layer 3 includes: an n-side first barrier layer 3bn; an n-side first well layer 3wn; an n-side first intermediate barrier layer 3mn; a well layer 3w2 (n-side second well layer); an intermediate barrier layer 3m2; a well layer 3w3; and a p-side first barrier layer 3bp that are laminated in this order from the side of the n-side layer 2. The n-side first well layer 3wn is a well layer located closest to the n-side layer 2 among the well layers. The n-side first intermediate barrier layer 3mn has a smaller band gap than that of the n-side first barrier layer 3bn. The well layer 3w2 is a well layer located at the second shortest distance from the n-side layer. The intermediate barrier layer 3m2 has a larger band gap than that of the n-side first intermediate barrier layer 3mn.

FIG. 2B shows an example of an energy-band structure (hereinafter simply referred to as a “band structure”) of the light-emitting layer 3 with the above-mentioned structure. FIG. 2B is a schematic diagram showing the magnitude relationship between band gaps. The same goes for the following drawings that illustrate the band structures.

In this embodiment, a well layer positioned between the n-side first barrier layer 3bn and the n-side first intermediate barrier layer 3mn is referred to as the n-side first well layer 3wm. By such naming, this well layer is distinguished from other well layers.

In the nitride semiconductor light-emitting element 10 with the structure mentioned above, the band gap of the n-side first intermediate barrier layer 3mn is set smaller than that of the n-side first barrier layer 3bn, so that the amount of injection of electrons into the well layers 3w2 and 3w3 can be increased. Thus, the probability of recombination between electrons and holes in the well layers (well layers 3w2 and 3w3) on both sides of the intermediate barrier layer 3m2 can be increased. Thus, the nitride semiconductor light-emitting element can decrease the forward voltage and improve the luminous efficiency.

In other words, in the light-emitting layer with a multiple quantum well structure, electrons tend to be injected more into the n-side well layer, but less into the central well layer. In contrast, holes tend to be less present at the n-side well layer. The electrons are less injected into the center well layer, reducing the probability of recombination between the electrons and holes present at this well layer, thus increasing the forward voltage. Such tendencies become remarkable as the dislocation density decreases.

On the other hand, in the first embodiment, the band gap in the n-side first intermediate barrier layer 3mn is set smaller than the band gap in the n-side first barrier layer 3bn, allowing electrons to easily flow into the central well layer from the n-side layer 2. In this way, the forward voltage can be reduced.

Furthermore, the nitride semiconductor light-emitting element 10 can improve the luminous efficiency. The luminous efficiency is represented, for example, by the slope efficiency (light output (a.u.)/current (mA)) that is defined by a light output relative to a current value. The reasons why the luminous efficiency is improved will be considered as follows. First, holes in the light-emitting layer tend to be less present toward the n side, thus making it difficult to enhance the luminous efficiency in the well layer close to the n-side layer 2, for example, the n-side first well layer 3wn. For this reason, the band gap of the n-side first intermediate barrier layer 3mn is made lower to decrease the amount of electrons in the n-side first well layer 3wn, while relatively increasing the amount of electrons in other well layers. In this way, it is considered that the luminous efficiency in other well layers can be relatively improved, so that the luminous efficiency of the nitride semiconductor light-emitting element 10 can be improved.

Moreover, in the nitride semiconductor light-emitting element 10, each of the band gap of the n-side first barrier layer 3bn and the band gap of the intermediate barrier layer 3m2 is set larger than that of the n-side first intermediate barrier layer 3mn. Thus, the electrons and holes can be confined in the light-emitting layer 3, which can efficiently recombine the electrons with the holes in the well layer.

That is, when setting each of the band gap of the n-side first barrier layer 3bn and the band gap of the intermediate barrier layer 3m2 smaller than that of the n-side first intermediate barrier layer 3mn, the barrier for confining the electrons and holes in the light-emitting layer. 3 becomes lower. In this case, the confinement of the electrons and holes in the light-emitting layer 3 becomes weak, which reduces the probability of recombination between the electrons and holes in the light-emitting layer 3. In such a structure, the luminous efficiency in a low-current range, for example, of 20 mA or lower is difficult to improve.

As mentioned above, in the nitride semiconductor light-emitting element 10, the band gap of the n-side first intermediate barrier layer 3mn is set smaller than that of each of the n-side first barrier layer 3bn and the intermediate barrier layer 3m2. This structure can achieve the nitride semiconductor light-emitting element 10 that reduces the forward voltage and enhances the luminous efficiency.

In the nitride semiconductor light-emitting element 10, for example, the n-side first barrier layer 3bn can be made of a nitride semiconductor represented by In_{b1}Ga_{1-b1}N (0≦b1<1), and the n-side first intermediate barrier layer 3mn can be made of a nitride semiconductor represented by Inₘ₁Ga₁₋ₘ₁N (0<m1<1). In this case, an In composition b1 of the n-side first barrier layer 3bn is set smaller than an In composition m1 of then-side first intermediate barrier layer 3mn. Thus, the band gap of the n-side first barrier layer 3bn is set larger than that of the n-side first intermediate barrier layer 3mn. The n-side first barrier layer 3bn is formed, for example, of GaN, while the n-side first intermediate barrier layer 3mn is formed, for example, of InGaN. Each of the n-side first well layer 3wn, the well layer 3w2, and the well layer 3w3 is made of a nitride semiconductor that is represented by In_{w}Ga_{1-w}N (0<w<1), in which an In composition w is larger than an In composition m1 of the n-side first intermediate barrier layer 3mn. The n-side first well layer 3wn, the well layer 3w2, and the well layer 3w3 can be made of nitride semiconductors, for example, having the same band gap. Note that in the present specification, a three-element nitride semiconductor containing In, Ga, and N can be simply referred to as “InGaN” in some cases.

When the n-side first barrier layer 3bn is made of In_{b1}Ga_{1-b1}N, and the n-side first intermediate barrier layer 3mn is made of Inₘ₁Ga₁₋ₘ₁N, preferably, an In composition b1 of the n-side first barrier layer 3bn is set at 0≦b1<0.1; an In composition m1 of the n-side first intermediate barrier layer 3mn is set at 0<m1<0.2; and b1 and m1 satisfy the relationship of b1<m1. As the In composition ratio becomes larger, the crystallinity tends to deteriorate. Taking this tendency into consideration, the In composition is preferably set within such a range. At this time, the In composition w of each of the n-side first well layer 3wn, the well layer 3w2, and the well layer 3w3 is set, for example, at 0.05≦w≦0.5. Note that the In composition w of the well layer is set such that a band gap thereof is smaller than that of any one of the barrier layers.

In the nitride semiconductor light-emitting element 10, the p-side first barrier layer 3bp can be formed, for example, by a nitride semiconductor having the same band gap as that of the n-side first barrier layer 3bn. When forming the p-side first barrier layer 3bp by the nitride semiconductor represented, for example, by In_{bf}Ga_{1-bf}N (0≦bf<1), the In composition bf is set to be the same as the In composition b1 of the n-side first barrier layer 3bn. The In composition bf of the p-side first barrier layer 3bp is preferably set within a range of 0≦bf<0.1, like the In composition b1 of the n-side first barrier layer 3bn.

In the nitride semiconductor light-emitting element 10, the intermediate barrier layer 3m2 can be formed, for example, by a nitride semiconductor having the same band gap as that of each of the n-side first barrier layer 3bn and the p-side first barrier layer 3bp. The intermediate barrier layer 3m2 can be formed by a nitride semiconductor represented by Inₘ₂Ga₁₋ₘ₂N (0≦m2<1). At this time, the In composition m2 of the intermediate barrier layer 3m2 can be selected from the same range as that of each of the In composition b1 of the n-side first barrier layer 3bn and the In composition bf of the p-side first barrier layer 3bp. For instance, the In composition m2 is set substantially equal to the In composition b1 and the In composition bf.

In the nitride semiconductor light-emitting element 10, the n-side first barrier layer 3bn and the n-side first intermediate barrier layer 3mn preferably contain n-type impurities. Thus, more electrons can be injected into the n-side first well layer 3wn and other well layers positioned closer to the p-side layer 4 compared with the n-side first well layer 3wn, thereby decreasing the forward voltage. In this case, an n-type impurity concentration in the n-side first intermediate barrier layer 3mn is preferably set lower than that of the n-side first barrier layer 3bn. This structure can suppress a decrease in the amount of holes caused by the addition of n-type impurities, and thereby can suppress reduction in the light output. Regarding the specific n-type impurity concentrations in the respective layers, while maintaining the magnitude relationship of the n-type impurity concentration between the n-side first barrier layer 3bn and the n-side first intermediate barrier layer 3mn, the n-type impurity concentration in the n-side first barrier layer 3bn is set at 1×10¹⁸/cm³ or more and less than 1×10²⁰/cm³, while the n-type impurity concentration in the n-side first intermediate barrier layer 3mn is set more than 1×10¹⁷/cm³ and less than 1×10¹⁹/cm³. The n-type impurity in use is, for example, Si.

Nitride semiconductor light-emitting elements according to second to eighth embodiments will be described below. When compared with the nitride semiconductor light-emitting element in the first embodiment, the nitride semiconductor light-emitting elements in the second to eighth embodiments differ in the structure of the light-emitting layer 3, and have substantially the same structure except for that point. The layers with the same designations can have the same structure unless otherwise specified. The structures of the light-emitting layers in the nitride semiconductor light-emitting elements according to second to eighth embodiments will be described below.

### Second Embodiment

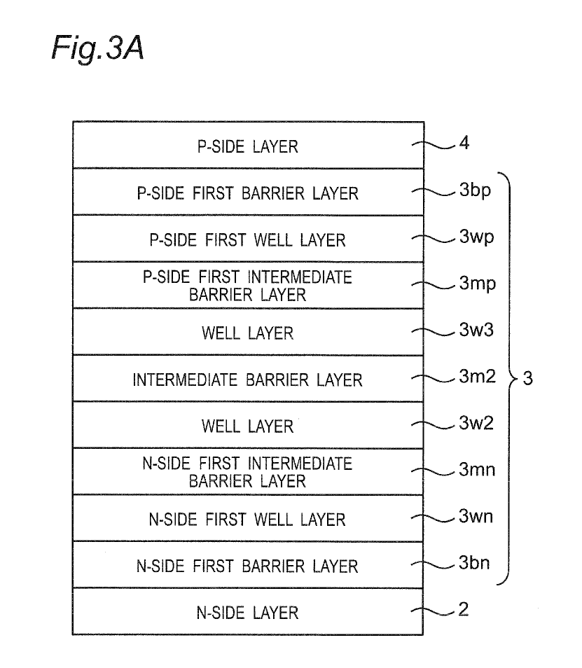

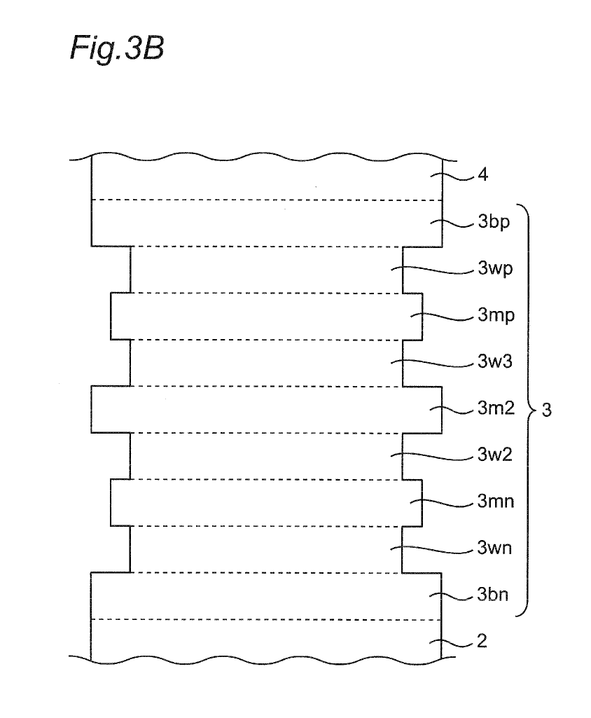

As illustrated in FIG. 3A, a light-emitting layer 3 of the nitride semiconductor light-emitting element in the second embodiment further includes a p-side first intermediate barrier layer 3mp and a p-side first well layer 3wp that are added in this order from the side of the n-side layer 2 and between the well layer 3w3 and p-side first barrier layer 3bp of the light-emitting layer 3 in the first embodiment. The band gap of the p-side first intermediate barrier layer 3mp is set smaller than that of the p-side first barrier layer 3bp. FIG. 3B shows an example of a band structure of the light-emitting layer 3 with the above-mentioned structure in the second embodiment. In the second embodiment, the well layer positioned between the p-side first barrier layer 3bp and the p-side first intermediate barrier layer 3mp is referred to as the p-side first well layer 3wp, and thereby distinguished from other well layers.

In this way, the band gap of the p-side first intermediate barrier layer 3mp is set smaller than that of the p-side first barrier layer 3bp, thereby making it possible to increase the number of injection of holes into the well layer 3w3, which is located away from the p-side layer, and other well layers closer to the n-side layer. Thus, a droop phenomenon can be suppressed, thereby making it possible to restrain the reduction in the luminous efficiency in a high-current range, for example, of 40 mA or higher.

In the light-emitting layer 3 of the second embodiment, for example, the p-side first intermediate barrier layer 3mp is made of a nitride semiconductor represented by Inₘ₃Ga₁₋ₘ₃N (0≦m3<1), and the p-side first barrier layer 3bp is made of a nitride semiconductor represented by In_{bf}Ga_{1-bf}N (0≦bf<1). In this case, an In composition m3 of the p-side first intermediate barrier layer 3mp is set larger than an In composition bf of the p-side first barrier layer 3bp. The band gap of each of the n-side first intermediate barrier layer 3mn and the p-side first intermediate barrier layer 3mp is preferably smaller than that of each of the n-side first barrier layer 3bn and the p-side first barrier layer 3bp.

Preferably, an In composition bf of the p-side first barrier layer 3bp is set at 0 bf<0.1; an In composition m3 of the p-side first intermediate barrier layer 3mp is set at 0<m3<0.2; and bf and m3 satisfy the relationship of bf<m3. This structure can efficiently achieve the confinement of electrons into the light-emitting layer 3 as well as the relief of concentration of holes on the p-side first well layer 3p1. At this time, the In composition w of each of the n-side first well layer 3wn, the well layer 3w2, and the well layer 3w3 is set, for example, at 0.05 w 0.5. Note that the In composition w of the well layer is set such that a band gap thereof is smaller than that of any one of the barrier layers.

The n-side first barrier layer 3bn and the p-side first barrier layer 3bp can be made of nitride semiconductors, for example, having the same band gap. For example, supposing that the n-side first barrier layer 3bn is made of a nitride semiconductor represented by In_{b1}Ga_{1-b1}N (0≦b1<1), and the p-side first barrier layer 3bp is made of a nitride semiconductor represented by In_{bf}Ga_{1-bf}N (0≦bf<1), the In composition b1 of the n-side first barrier layer 3bn is equal to the In composition bf of the p-side first barrier layer 3bp. In this case, both the In composition b1 and the In composition bf are set to zero (0), whereby each of the n-side first barrier layer 3bn and the p-side first barrier layer 3bp can be made of GaN. The n-side first barrier layer 3bn and the p-side first barrier layer 3bp are made of the layers with the large band gap in this way, which is advantageous in terms of confinement of carriers into the light-emitting layer 3.

The n-side first intermediate barrier layer 3mn and the p-side first intermediate barrier layer 3mp can be made of nitride semiconductors, for example, having the same band gap. For example, when forming the n-side first intermediate barrier layer 3mn by a nitride semiconductor represented by Inₘ₁Ga₁₋ₘ₁N (0<m1<1), the p-side first intermediate barrier layer 3mp is made of a nitride semiconductor represented by Inₘ₃Ga₁₋ₘ₃N (0<m3<1), in which an In composition m3 is the same as an In composition m1 of the n-side first intermediate barrier layer 3mn.

Each of the p-side first barrier layer 3bp and the p-side first intermediate barrier layer 3mp is preferably either an undoped layer or a layer having an n-type impurity concentration lower than that of the n-side first intermediate barrier layer 3mn. This structure can suppress a decrease in the number of holes in the well layer (p-side first well layer 3wp) close to the p-side layer 4, whereby the well layer with high luminous efficiency located close to the p-side layer 4 can effectively emit the light therefrom. Note that the term “undoped layer” as used herein means a layer doped with neither n-type impurities nor p-type impurities intentionally. The undoped layer can be defined as a layer in which an impurity concentration is below a detection limit of analysis, such as secondary ion mass spectrometry (SIMS), etc. All the well layers included in the light-emitting layer 3 are typically undoped layers.

### Third Embodiment

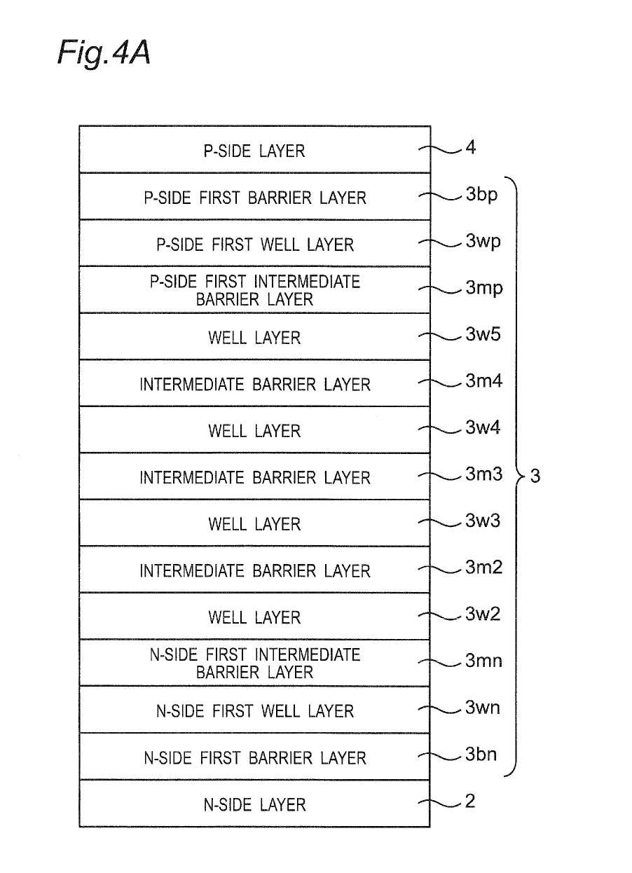

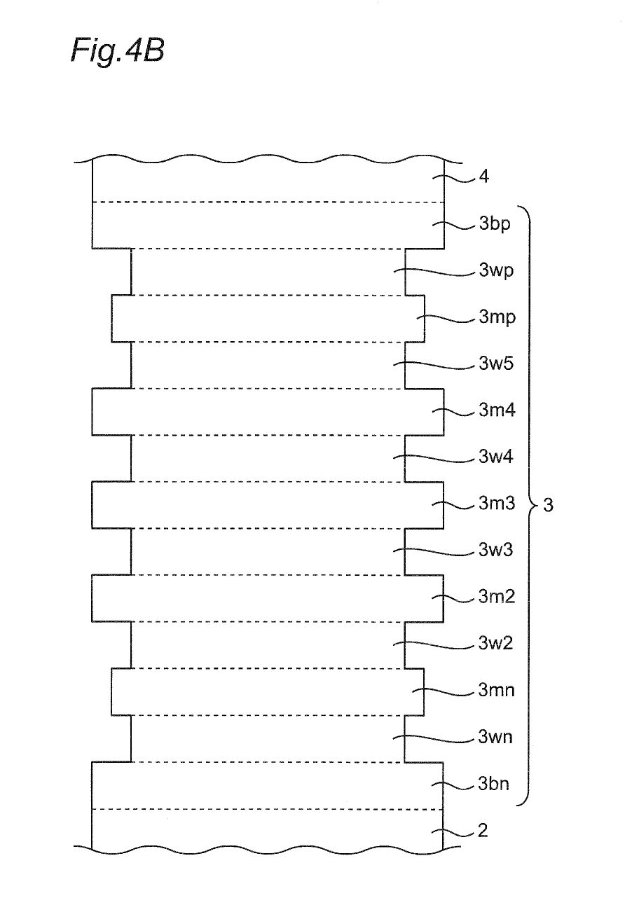

As illustrated in FIG. 4A, a light-emitting layer 3 of the nitride semiconductor light-emitting element in the third embodiment further includes an intermediate barrier layer 3m3, a well layer 3w4, an intermediate barrier layer 3m4, a well layer 3w5, a p-side first intermediate barrier layer 3mp, and a p-side first well layer 3wp that are added in this order from the side of the n-side layer 2 and between the well layer 3w3 and p-side first barrier layer 3bp of the light-emitting layer 3 in the first embodiment. In other words, the light-emitting layer 3 of the nitride semiconductor light-emitting element in the third embodiment further includes the intermediate barrier layer 3m3, the well layer 3w4, the intermediate barrier layer 3m4, and the well layer 3w5 that are added in this order from the side of the n-side layer 2 and between the well layer 3w3 and p-side first intermediate barrier layer 3mp of the light-emitting layer 3 in the second embodiment. FIG. 4B shows an example of a band structure of the light-emitting layer 3 with the above-mentioned structure in the third embodiment.

The well layer 3w3 (intermediate well layer) is a well layer located at the third shortest distance from the n-side layer 2. The band gap of the intermediate barrier layer 3m3 (second intermediate barrier layer) is larger than that of the n-side first intermediate barrier layer 3mn. Thus, the amount of holes flowing out of the n-side layer 2 can be reduced without being recombined with electrons, compared to the case in which the band gap of the intermediate barrier layer 3m3 is as low as the n-side first intermediate barrier layer 3mn. Therefore, the luminous efficiency in a low-current range, for example, of 20 mA or lower can be improved. The intermediate barrier layer 3m3 and the intermediate barrier layer 3m4 can be made of nitride semiconductors that have the same band gap as the intermediate barrier layer 3m2. For example, the intermediate barrier layer 3m3 and the intermediate barrier layer 3m4 can be formed by nitride semiconductors that are represented by Inₘ₄Ga₁₋ₘ₄N (0≦m4<1) and Inₘ₅Ga₁₋ₘ₅N (0≦m5<1), respectively, in which the In compositions m4 and m5 are set to be the same as the In composition m2 of the intermediate barrier layer 3m2. The intermediate barrier layers 3m2, 3m3, and 3m4 may have the same band gap as that of the n-side first barrier layer 3bn and the p-side first barrier layer 3bp. The intermediate barrier layers 3m2, 3m3, and 3m4 are made of, e.g., GaN.

The intermediate barrier layer 3m2 may contain n-type impurities. When doping n-type impurities into the intermediate barrier layer 3m2, the concentration of electrons in the well layers close to the intermediate barrier layer 3m2 can be increased, while the concentration of holes is decreased. Thus, an n-type impurity concentration in the intermediate barrier layer 3m2 is preferably set lower than that of the n-side first barrier layer 3bn, like the n-side first intermediate barrier layer 3mn. The specific value of the n-type impurity concentration can be selected from the same range as that for the n-side first intermediate barrier layer 3mn. Furthermore, preferably, n-type impurities are doped into an intermediate barrier layer located at a position where the concentration of electrons is more likely to decrease, while any other intermediate barrier layer is undoped. In this way, the forward voltage can be reduced while suppressing the reduction in the light output. Specifically, among the well layers and the intermediate barrier layers sandwiched between the adjacent well layers (including the n-side first intermediate barrier layer 3mn and the p-side first intermediate barrier layer 3mp), preferably, one or more layers of them are formed to contain n-type impurities in the order of being closer to the n-side layer 2, while at least one layer closest to the p-side layer 4 is formed as an undoped layer. Specifically, the number of intermediate barrier layers containing n-type impurities is preferably less than 80% of the total number of all the intermediate barrier layers. With the structure satisfying such a range, the forward voltage can be reduced, and the same level or more of light output can be obtained, compared to the case in which all the intermediate barrier layers are undoped. For example, when five intermediate barrier layers are formed as shown in FIG. 4A, a range into which n-type impurities are doped may be set from the n-side first intermediate barrier layer 3mn to the intermediate barrier layer 3m3 at a maximum, while other layers located closer to the p-side layer 4 may be undoped.

The well layer 3w4 and the well layer 3w5 can be made of nitride semiconductors that have the same band gap as that of each of the n-side first well layer 3wn, the well layer 3w2, the well layer 3w3, and the p-side first well layer 3wp. For example, each of the well layers 3w4 and 3w5 is made of the nitride semiconductor represented by In_{w}Ga_{1-w}N (0≦w<1), in which an In composition w is larger than an In composition m1 of the n-side first intermediate barrier layer 3mn.

### Fourth Embodiment

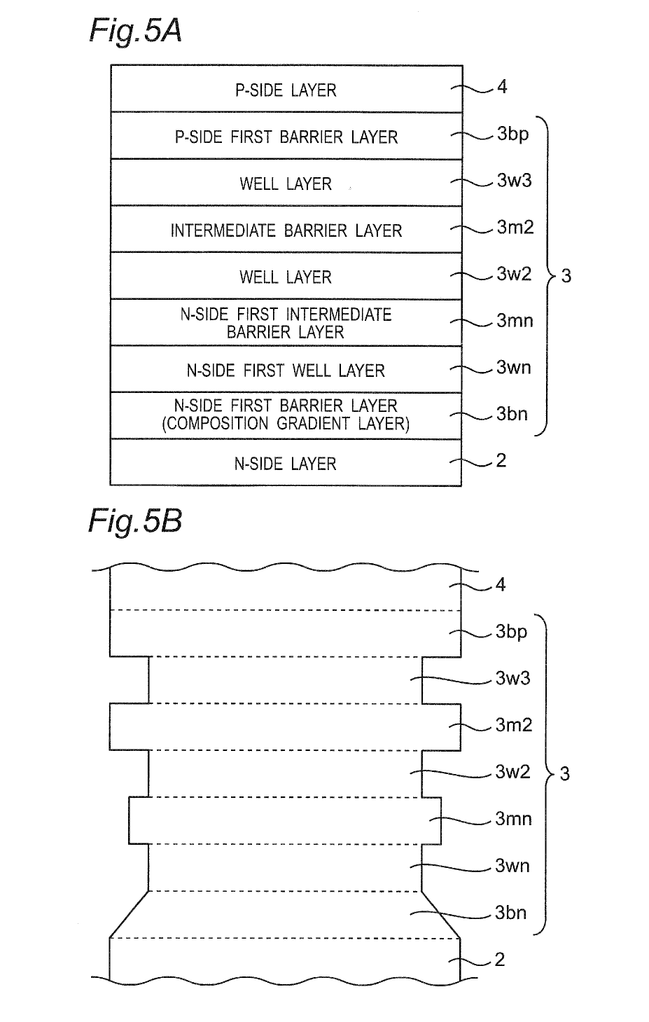

As illustrated in FIG. 5A, a light-emitting layer 3 of the nitride semiconductor light-emitting element in the fourth embodiment has a structure in which an n-side first barrier layer 3bn is formed as a composition gradient layer in the light-emitting layer 3 of the first embodiment.

Specifically, the n-side first barrier layer 3bn in the fourth embodiment is configured such that its band gap decreases from the n-side layer 2 toward the n-side first well layer 3wn. For instance, suppose that a layer of the n-side layer 2 in contact with the first barrier layer 3bn is an n-type contact layer made of GaN, and the n-side first well layer 3wn is made of InGaN. In this case, the In composition of the n-side first barrier layer 3bn is gradually increased from the n-type contact layer side, and becomes substantially equal to the In composition of the n-side first well layer 3wn at the interface thereof with the n-side first well layer 3wn. FIG. 5B shows an example of a band structure of the light-emitting layer 3 with the above-mentioned structure in the fourth embodiment. In this way, in the light-emitting layer 3 of the nitride semiconductor light-emitting element 10, the n-side first barrier layer 3bn may be formed as the composition gradient layer. Also in the light-emitting layer of the nitride semiconductor light-emitting element of the second or third embodiment, the n-side first barrier layer 3bn can be formed as the composition gradient layer. In this case, the magnitude relationship about the band gap with respect to the n-side first intermediate barrier layer 3mn is determined, for example, by comparing the maximum band gap in the composition gradient layer. Alternatively or additionally, an average band gap of the composition gradient layer may be compared, or further the minimum band gap in the composition gradient layer may be compared. Note that in Examples 1 and 2 to be mentioned later, each of the layers including the n-side first barrier layer 3bn is not the composition gradient layer, but a single composition layer.

### Fifth Embodiment

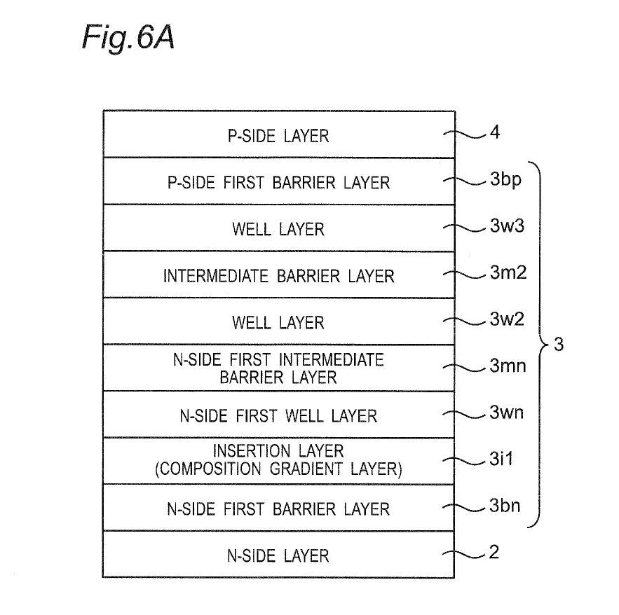

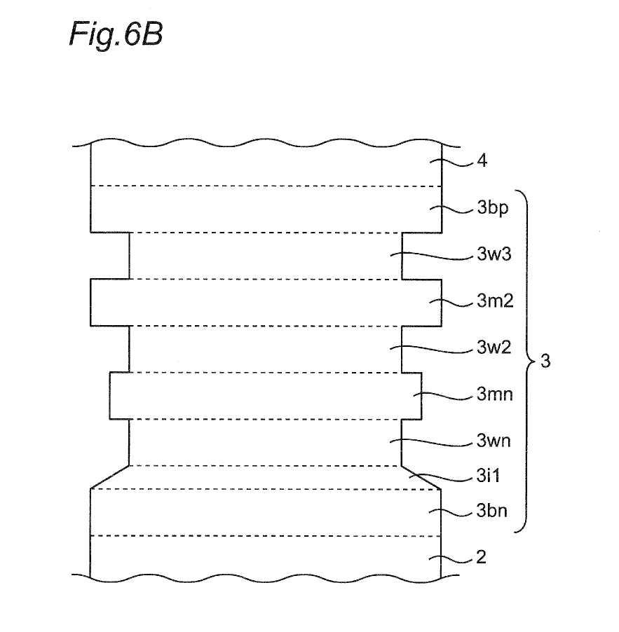

As illustrated in FIG. 6A, a light-emitting layer 3 of the nitride semiconductor light-emitting element in the fifth embodiment has a structure in which an insertion layer 3i1 is added as a composition gradient layer between the first barrier layer 3bn and the n-side first well layer 3wn in the light-emitting layer 3 of the first embodiment. The insertion layer 3i1 is configured such that its band gap decreases from the first barrier layer 3bn side toward the n-side first well layer 3wn. For example, a part of the insertion layer 3i1 in contact with the first barrier layer 3bn has the same composition as the first barrier layer 3bn; the composition of the insertion layer 3i1 is gradually changed as it is far away from the first barrier layer 3bn; and a part of the insertion layer 3i1 in contact with the n-side first well layer 3wn has substantially the same composition as that of the n-side first intermediate barrier layer 3mn. FIG. 6B shows an example of a band structure of the light-emitting layer 3 with the above-mentioned structure in the fifth embodiment. In this way, the barrier layer and the well layer may not be in contact with each other, and the insertion layer 3i1 may be provided.

### Sixth Embodiment

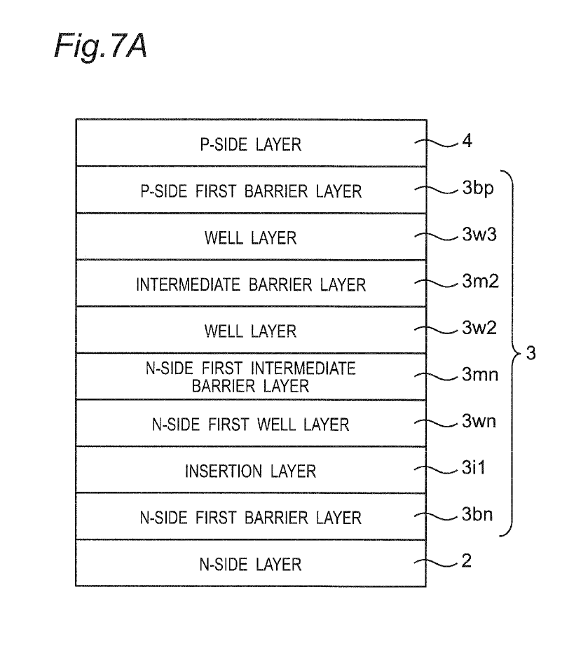

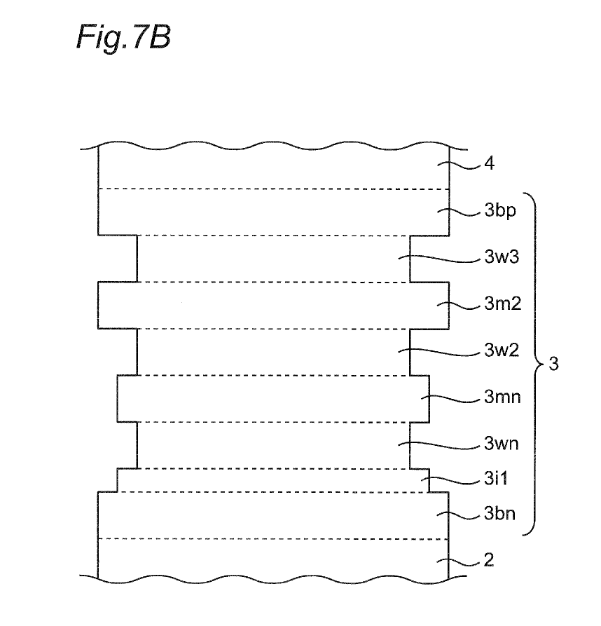

As illustrated in FIG. 7A, a light-emitting layer 3 of the nitride semiconductor light-emitting element in the sixth embodiment is similar to the light-emitting layer 3 in the fifth embodiment in that the insertion layer 3i1 is included between the n-side first barrier layer 3bn and the n-side first well layer 3wn in the light-emitting layer 3 of the first embodiment. However, the composition of the insertion layer 3i1 does not change in the thickness direction and is kept constant, and the band gap of the insertion layer 3i1 is set at a value between the band gap of the n-side first barrier layer 3bn and the band gap of the n-side first well layer 3wn. For example, when the n-side first barrier layer 3bn is made of GaN and the n-side first well layer 3wn is made of InGaN, the insertion layer 3i1 is made of InGaN in which its In composition is smaller than the In composition of the n-side first well layer 3wn. FIG. 7B shows an example of a band structure of the light-emitting layer 3 with the above-mentioned structure in the sixth embodiment. In this way, the insertion layer 3i1 is not limited to the composition gradient layer, but may be formed with the composition and thickness capable of exhibiting the effects of the barrier layer, such as the n-side first barrier layer 3bn.

### Seventh Embodiment

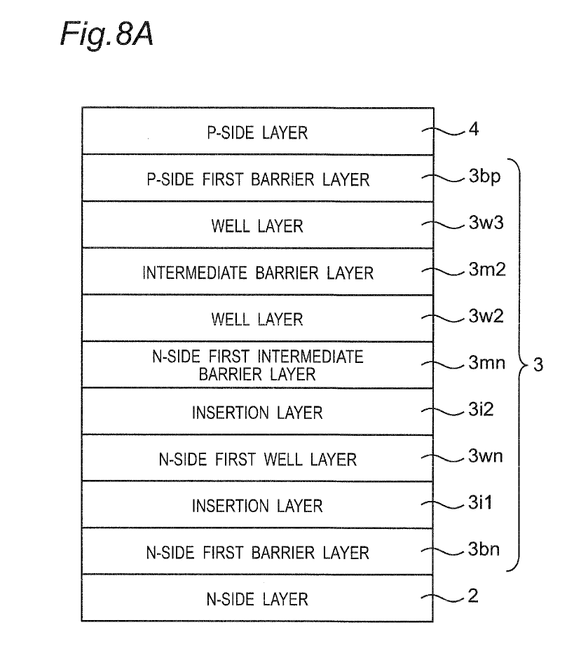

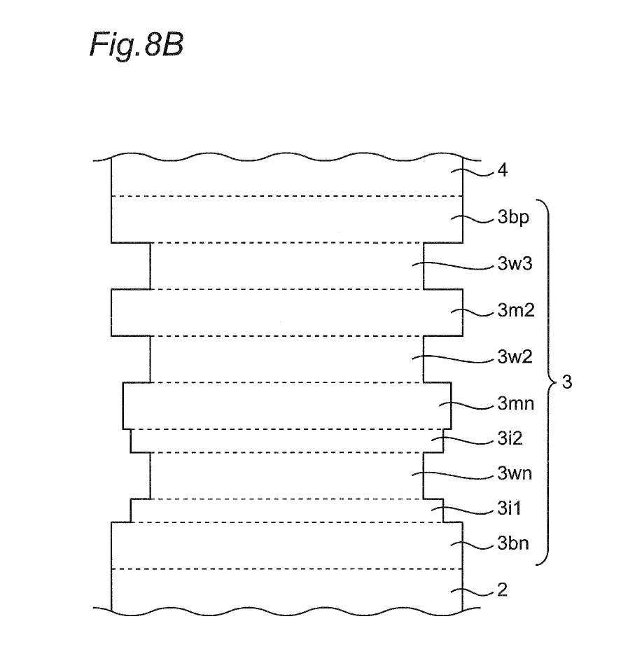

As illustrated in FIG. 8A, a light-emitting layer 3 of the nitride semiconductor light-emitting element in the seventh embodiment differs from the light-emitting layer 3 in the first embodiment in that the insertion layer 3i1 is included between the n-side first barrier layer 3bn and the n-side first well layer 3wn, and further that another insertion layer 3i2 is included between the n-side first well layer 3wn and the n-side first intermediate barrier layer 3mn. Each of the band gaps of the insertion layers 3i1 and 3i2 is set smaller than that of the n-side first intermediate barrier layer 3m1, and larger than that of the n-side first well layer 3wn. The band gap of the insertion layer 3i1 and the band gap of the insertion layer 3i2 are preferably set at the same value or alternatively may be different. FIG. 8B shows an example of a band structure of the light-emitting layer 3 with the above-mentioned structure in the seventh embodiment. In this way, a plurality of insertion layers 3i1 and 3i2 can also be provided.

### Eighth Embodiment

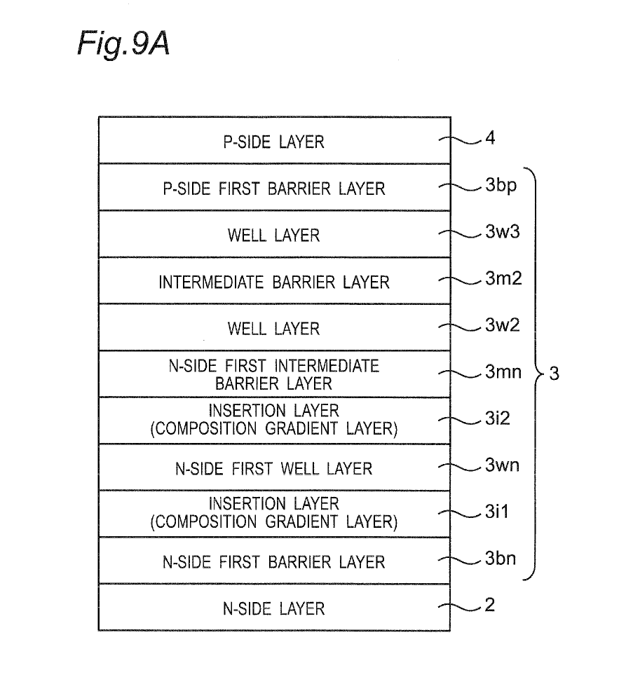

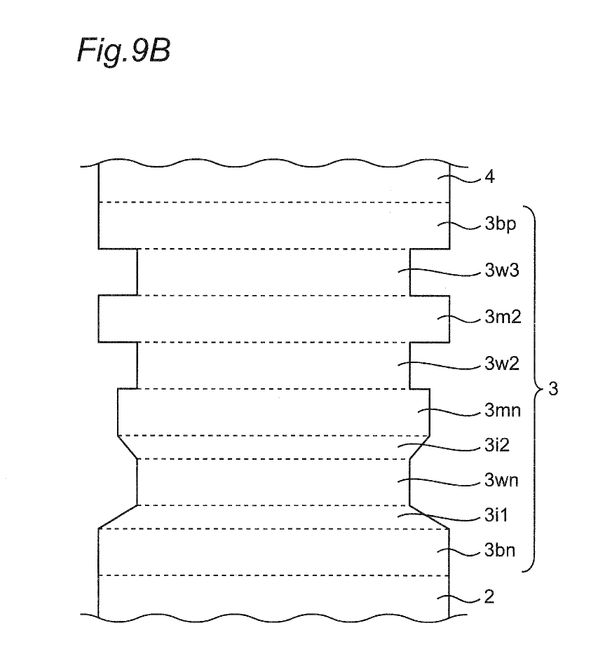

As illustrated in FIG. 9A, a light-emitting layer 3 of the nitride semiconductor light-emitting element in the eighth embodiment differs from the light-emitting layer 3 in the first embodiment in that the insertion layer 3i1 is included between the first barrier layer 3bn and the n-side first well layer 3wn, and further that another insertion layer 3i2 is included between the n-side first well layer 3wn and the n-side first intermediate barrier layer 3mn. In this aspect, the light-emitting layer 3 in the eighth embodiment is similar to the light-emitting layer 3 in the seventh embodiment. However, the light-emitting layer 3 in the eighth embodiment differs from the light-emitting layer 3 in the seventh embodiment in that the insertion layer 3i1 and the insertion layer 3i2 are composition gradient layers.

Specifically, the insertion layer 3i1 is configured such that its band gap decreases from the n-side first barrier layer 3bn toward the n-side first well layer 3wn. The insertion layer 3i2 is configured such that its band gap increases from the n-side first well layer 3wn toward the n-side first intermediate barrier layer 3mn. FIG. 9B shows an example of a band structure of the light-emitting layer 3 with the above-mentioned structure in the eighth embodiment.

The insertion layers to be mentioned in the fifth to eighth embodiments are formed not to substantially impair the functions of the well layers and barrier layers for various purposes. For convenience of drawing, the figures illustrate the insertion layers in the substantially same thickness as that of each of the well layers and the barrier layers. In practice, the insertion layer is an ultrathin layer having a thickness of, for example, approximately 1 nm or less. The position for formation of the insertion layer can be selected from a variety of positions depending on the purposes. Specifically, the insertion layer may be formed between the intermediate barrier layer and the well layer, or between the p-side barrier layer and the well layer.

While nitride semiconductor light-emitting elements in the first to eighth embodiments have been described above, the dislocation density of such a nitride semiconductor light-emitting element 10 in the first to eighth embodiments is preferably less than 1×10⁸/cm². Furthermore, the dislocation density is preferably 5×10⁷/cm² or less. Thus, the functions and effects explained in the respective embodiments can be remarkably exhibited. Normally, the dislocation density does not change significantly from the n-side layer 2 to the p-side layer 4. For this reason, the dislocation density may be evaluated at any position. To decrease the degree of the reduction in the output at a high temperature, the dislocation density of the light-emitting layer 3 is considered to be preferably less than 1×10⁸/cm². Thus, the dislocation density of the light-emitting element is preferably evaluated at the light-emitting layer 3 or in the vicinity thereto. Note that such a layer with a low dislocation density can be obtained, for example, by forming an AlN buffer layer, which is not polycrystalline but monocrystalline, on a surface of a sapphire substrate, and growing the low-dislocation density layer on the buffer layer. Here, the dislocation density of the light-emitting layer 3 can be evaluated by a transmission electron microscope (TEM) or a cathodoluminescence (CL) method. The CL method involves exciting carriers in crystals by irradiating the crystals with an electron beam and carrying out the spectral analysis of emission for the light generated upon recombination.

### Examples

Examples will be described below.

In Example 1, a nitride semiconductor light-emitting element shown in Table 1 was fabricated. In Example 2, a nitride semiconductor light-emitting element shown in Table 2 was fabricated. In Comparative Example 1, a nitride semiconductor light-emitting element shown in Table 3 was fabricated. Specifically, in any of Examples, the semiconductor layers were grown on a sapphire substrate, and singulation was performed with a chip size set at 650 μm×650 μm. In any of the Examples, a dislocation density measured by the CL method after the singulation was approximately 5×10⁷/cm².

TABLE 1

| | | Thickness | Doping of |
|---|---|---|---|
| Layer name | Composition | (nm) | impurities |
| p-side third layer | GaN | 27 | Mg 1 to 5 × |
| (p-type contact layer) | | | 10²⁰/cm³ |
| p-side second layer | GaN | 40 | Undoped |
| p-side first layer | Al_{0.2}Ga_{0.8}N | 10 | Mg 1 × |
| | | | 10²⁰/cm³ |
| p-side first barrier | GaN | 4.5 | Undoped |
| layer 3bp | | | |
| p-side first well | In_{0.15}Ga_{0.85}N | 3.6 | Undoped |
| layer 3wp | | | |
| p-side first | GaN | 4.5 | Undoped |
| intermediate barrier | | | |
| layer 3mp | | | |
| Well layer 3w5 | In_{0.15}Ga_{0.85}N | 3.6 | Undoped |
| Intermediate barrier | GaN | 4.5 | Undoped |
| layer 3m4 | | | |
| Well layer 3w4 | In_{0.15}Ga_{0.85}N | 3.6 | Undoped |
| Intermediate barrier | GaN | 4.5 | Undoped |
| layer 3m3 | | | |
| Well layer 3w3 | In_{0.15}Ga_{0.85}N | 3.6 | Undoped |
| Intermediate barrier | GaN | 4.5 | Undoped |
| layer 3m2 | | | |
| Well layer 3w2 | In_{0.15}Ga_{0.85}N | 3.6 | Undoped |
| n-side first | In_{0.02}Ga_{0.98}N | 4.5 | Undoped |
| intermediate barrier | | | |
| layer 3mn | | | |
| n-side first well | In_{0.15}Ga_{0.85}N | 3.6 | Undoped |
| layer 3wn | | | |
| n-side first barrier | GaN | 10 | Si 1 × |
| layer 3bn | | | 10¹⁹/cm³ |
| n-side second layer | GaN | 5000 | Si 5 × |
| (n-type contact layer) | | | 10¹⁸/cm³ |
| n-side first layer | GaN | 5000 | Undoped |
| Buffer layer | AlN | Thin film | Undoped |

TABLE 2

| | | Thickness | Doping of |
|---|---|---|---|
| Layer name | Composition | (nm) | impurities |
| p-side third layer | GaN | 27 | Mg 1 to 5 × |
| (p-type contact layer) | | | 10²⁰/cm³ |
| p-side second layer | GaN | 40 | Undoped |
| p-side first layer | Al_{0.2}Ga_{0.8}N | 10 | Mg 1 × |
| | | | 10²⁰/cm³ |
| p-side first barrier | GaN | 4.5 | Undoped |
| layer | | | |
| p-side first well | In_{0.15}Ga_{0.85}N | 3.6 | Undoped |
| layer 3wp | | | |
| p-side first | In_{0.02}Ga_{0.98}N | 4.5 | Undoped |
| intermediate barrier | | | |
| layer 3mp | | | |
| Well layer 3w5 | In_{0.15}Ga_{0.85}N | 3.6 | Undoped |
| Intermediate barrier | GaN | 4.5 | Undoped |
| layer 3m4 | | | |
| Well layer 3w4 | In_{0.15}Ga_{0.85}N | 3.6 | Undoped |
| Intermediate barrier | GaN | 4.5 | Undoped |
| layer 3m3 | | | |
| Well layer 3w3 | In_{0.15}Ga_{0.85}N | 3.6 | Undoped |
| Intermediate barrier | GaN | 4.5 | Undoped |
| layer 3m2 | | | |
| Well layer 3w2 | In_{0.15}Ga_{0.85}N | 3.6 | Undoped |
| n-side first | In_{0.02}Ga_{0.98}N | 4.5 | Undoped |
| intermediate barrier | | | |
| layer 3mn | | | |
| n-side first well | In_{0.15}Ga_{0.85}N | 3.6 | Undoped |
| layer 3wn | | | |
| n-side first barrier | GaN | 4.5 | Si 1 × |
| layer 3bn | | | 10¹⁹/cm³ |
| n-side second layer | GaN | 5000 | Si 5 × |
| (n-type contact layer) | | | 10¹⁸/cm³ |
| n-side first layer | GaN | 5000 | Undoped |
| Buffer layer | AlN | Thin film | Undoped |

TABLE 3

| | | Thickness | Doping of |
|---|---|---|---|
| Layer name | Composition | (nm) | impurities |
| p-side third layer | GaN | 27 | Mg 1 to 5 × |
| (p-type contact layer) | | | 10²⁰/cm³ |
| p-side second layer | GaN | 40 | Undoped |
| p-side first layer | Al_{0.2}Ga_{0.8}N | 10 | Mg 1 × |
| | | | 10²⁰/cm³ |
| Barrier layer | GaN | 4.5 | Undoped |
| Well layer | In_{0.15}Ga_{0.85}N | 3.6 | Undoped |
| Intermediate barrier | GaN | 4.5 | Undoped |
| layer | | | |
| Well layer | In_{0.15}Ga_{0.85}N | 3.6 | Undoped |
| Intermediate barrier | GaN | 4.5 | Undoped |
| layer | | | |
| Well layer | In_{0.15}Ga_{0.85}N | 3.6 | Undoped |
| Intermediate barrier | GaN | 4.5 | Undoped |
| layer | | | |
| Well layer | In_{0.15}Ga_{0.85}N | 3.6 | Undoped |
| Intermediate barrier | GaN | 4.5 | Undoped |
| layer | | | |
| Well layer | In_{0.15}Ga_{0.85}N | 3.6 | Undoped |
| Intermediate barrier | GaN | 4.5 | Undoped |
| layer | | | |
| Well layer | In_{0.15}Ga_{0.85}N | 3.6 | Undoped |
| Barrier layer | GaN | 10 | Si 1 × |
| | | | 10¹⁹/cm³ |
| n-side second layer | GaN | 5000 | Si 5 × |
| (n-type contact layer) | | | 10¹⁸/cm³ |
| n-side first layer | GaN | 5000 | Undoped |
| Buffer layer | AlN | (Thin film) | Undoped |

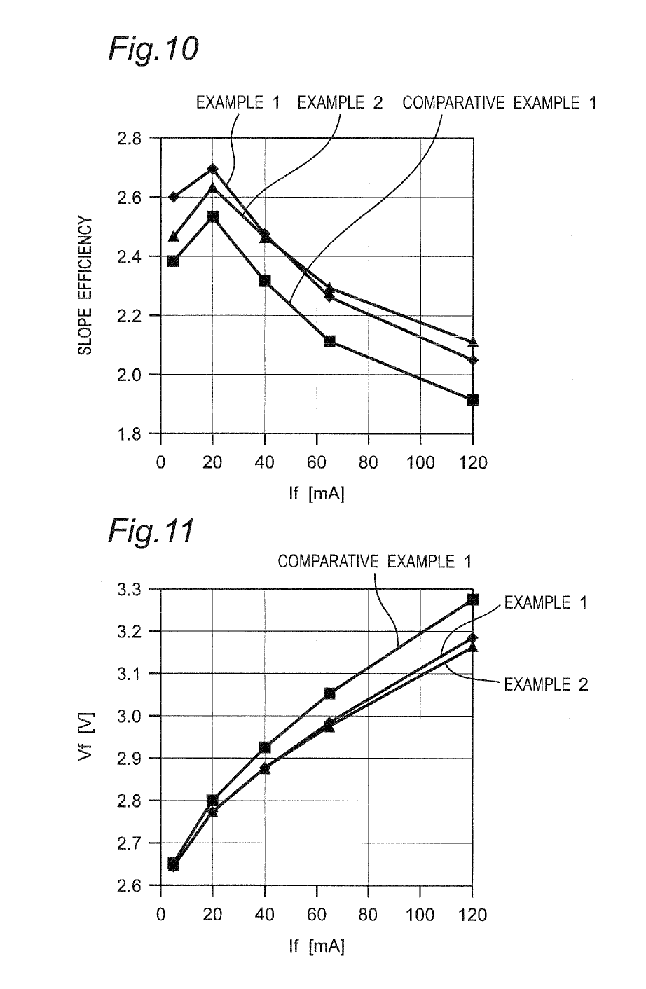

The nitride semiconductor light-emitting elements in Examples 1 and 2 and the nitride semiconductor light-emitting element in Comparative Example 1 that were fabricated in the way mentioned above were evaluated for a slope efficiency (light output (a.u.)/current (mA)), which was defined as a ratio of the light output to the current value, as well as a forward voltage Vf. FIGS. 10 and 11 show evaluation results of the respective slope efficiencies (light output (a.u.)/current (mA)) and the forward voltages Vf. In each of the graphs, the horizontal axis indicates an If (forward current). As a result, it was confirmed that either of the nitride semiconductor light-emitting elements in Examples 1 and 2 could reduce the forward voltage and enhance the slope efficiency, as compared with the nitride semiconductor light-emitting element in Comparative Example 1.

### DESCRIPTION OF REFERENCE NUMERALS

1: Substrate
2: n-side layer (n-side semiconductor layer)
3: Light-emitting layer
3bn: n-side first barrier layer
3wn: n-side first well layer
3mn: n-side first intermediate barrier layer
3w2, 3w3, 3w4, 3w5: Well layer
3m2, 3m3: Intermediate barrier layer
3bp: p-side first barrier layer
3wp: p-side first well layer
3mp: p-side first intermediate barrier layer
4: p-side layer (p-side semiconductor layer)
6: Overall electrode
7: p-electrode
10: Nitride semiconductor light-emitting element

What is claimed is:

1. A nitride semiconductor light-emitting element comprising:
a n-side layer;
a p-side layer; and
a light-emitting layer having a multiple quantum well structure, the light-emitting layer being located between the n-side layer and the p-side layer,
wherein the light-emitting layer includes:
a n-side first barrier layer,
a plurality of well layers, including a n-side first well layer, a n-side second well layer, and one or more additional well layers, and
a plurality of intermediate layers, including a n-side first intermediate barrier layer and one or more additional intermediate barrier layers,
wherein the layers of the light-emitting layer are disposed in the following order from a side of the n-side layer:
the n-side first barrier layer,
the n-side first well layer,
the n-side first intermediate barrier layer,
the n-side second well layer,
a first additional intermediate barrier layer among the one or more additional intermediate barrier layers, and
a first additional well layer among the one or more additional well layers,
wherein a band gap of the n-side first intermediate barrier layer is smaller than a band gap of the n-side first barrier layer, and
wherein a band gap of each of the one or more additional intermediate barrier layers is larger than a band gap of the n-side first intermediate barrier layer.

2. The nitride semiconductor light-emitting element according to claim 1,
wherein the n-side first barrier layer and the n-side first intermediate barrier layer contain n-type impurities, and
wherein a n-type impurity concentration of the n-side first barrier layer is larger than a n-type impurity concentration of the n-side first intermediate barrier layer.

3. The nitride semiconductor light-emitting element according to claim 1,
wherein the n-side first barrier layer is made of a nitride semiconductor represented by In_{b1}Ga_{1-b1}N (0≦b1<0.1), and the n-side first intermediate barrier layer is made of a nitride semiconductor represented by Inₘ₁Ga₁₋ₘ₁N (0<m1<0.2, b1<m1).

4. The nitride semiconductor light-emitting element according to claim 1,
wherein the light-emitting layer further includes, in the following order from a side of the p-side layer:
a p-side first barrier layer,
a p-side first well layer, and
a p-side first intermediate barrier layer, and
wherein a band gap of the p-side first intermediate barrier layer is smaller than a band gap of the p-side first barrier layer.

5. The nitride semiconductor light-emitting element according to claim 4, wherein the band gap of the n-side first intermediate barrier layer and the band gap of the p-side first intermediate barrier layer are smaller than the band gap of the n-side first barrier layer and the band gap of the p-side first barrier layer.

6. The nitride semiconductor light-emitting element according to claim 4, wherein each of the p-side first barrier layer and the p-side first intermediate barrier layer is (i) an undoped layer, or (ii) a layer having a n-type impurity concentration lower than that of the n-side first intermediate barrier layer.

7. The nitride semiconductor light-emitting element according to claim 4, wherein the p-side first barrier layer is made of a nitride semiconductor represented by In_{bf}Ga_{1-bf}N (0≦bf<0.1) and the p-side first intermediate barrier layer is made of a nitride semiconductor represented by Inₘ₃Ga₁₋ₘ₃N (0≦m3<0.2, bf<m3).

8. The nitride semiconductor light-emitting element according to claim 7, wherein the n-side first barrier layer and the p-side first barrier layer are made of GaN.

9. The nitride semiconductor light-emitting element according to claim 7, wherein an In composition of the n-side first intermediate barrier layer is the same or approximately the same as an In composition of the p-side first intermediate barrier layer.

10. The nitride semiconductor light-emitting element according to claim 1,
wherein the light-emitting layer further includes a second additional intermediate barrier layer located after the first additional well layer in order from the side of the n-side layer, and
wherein a band gap of the second additional intermediate barrier layer is larger than the band gap of the n-side first intermediate barrier layer.

11. The nitride semiconductor light-emitting element according to claim 1, wherein the one or more intermediate barrier layers contain n-type impurities.

12. The nitride semiconductor light-emitting element according to claim 1, wherein a dislocation density of the light-emitting layer or in the vicinity thereto is less than 1×10⁸/cm².

13. A nitride semiconductor light-emitting element comprising:
a n-side layer;
a p-side layer; and
a light-emitting layer having a multiple quantum well structure, the light-emitting layer being located between the n-side layer and the p-side layer,
wherein the light-emitting layer includes:
a n-side first barrier layer made of a nitride semiconductor represented by In_{b1}Ga_{1-b1}N (0≦b1<0.1);
a plurality of well layers, including a n-side first well layer, a n-side second well layer, a p-side first well layer, and one or more additional well layers,
a plurality of intermediate barrier layers, including a n-side first intermediate barrier layer made of a nitride semiconductor represented by Inₘ₁Ga₁₋ₘ₁N (0<m1<0.2, b1<m1), a p-side first intermediate barrier layer made of a nitride semiconductor represented by Inₘ₃Ga₁₋ₘ₃N (0≦m3<0.2), and one or more additional intermediate barrier layers, and
a p-side first barrier layer made of a nitride semiconductor represented by In_{bf}Ga_{1-bf}N (0≦bf<0.1, bf<m3),
wherein the layers of the light-emitting layer are disposed in the following order from a side of the n-side layer:
the n-side first barrier layer,
the n-side first well layer,
the n-side first intermediate barrier layer,
the n-side second well layer,
a first additional intermediate barrier layer among the one or more intermediate barrier layers,
a first additional well layer among the one or more well layers,
the p-side first intermediate barrier layer,
the p-side first well layer, and
the p-side first barrier layer, and
wherein a band gap of each of the one or more additional intermediate barrier layers is larger than a band gap of the n-side first intermediate barrier layer.

14. The nitride semiconductor light-emitting element according to claim 13,
wherein the n-side first barrier layer and the n-side first intermediate barrier layer contain n-type impurities, and
wherein a n-type impurity concentration of the n-side first barrier layer is larger than a n-type impurity concentration of the n-side first intermediate barrier layer.

15. The nitride semiconductor light-emitting element according to claim 14, wherein each of the p-side first barrier layer and the p-side first intermediate barrier layer is (i) an undoped layer, or (ii) a layer having a n-type impurity concentration lower than that of the n-side first intermediate barrier layer.

16. The nitride semiconductor light-emitting element according to claim 15, wherein the n-side first barrier layer and the p-side first barrier layer are made of GaN.

17. A nitride semiconductor light-emitting element comprising:
a n-side layer;
a p-side layer; and
a light-emitting layer having a multiple quantum well structure, the light-emitting layer being located between the n-side layer and the p-side layer,
wherein the light-emitting layer includes, in order from a side of the n-side layer:
a n-side first barrier layer,
a first well layer,
a first intermediate barrier layer having a band gap smaller than that of the n-side first barrier layer,
a second well layer;
a second intermediate barrier layer having a band gap larger than that of the first intermediate barrier layer,
a third well layer,
a third intermediate barrier layer having a band gap larger than that of the first intermediate barrier layer,
a fourth well layer,
a p-side first intermediate barrier layer,
a p-side first well layer, and
a p-side first barrier layer having a band gap larger than that of the p-side first intermediate barrier layer.

18. The nitride semiconductor light-emitting element according to claim 17,
wherein the n-side first barrier layer and the first intermediate barrier layer contain n-type impurities,
wherein a n-type impurity concentration of the n-side first barrier layer is larger than a n-type impurity concentration of the first intermediate barrier layer, and
wherein each of the p-side first barrier layer and the p-side first intermediate barrier layer is (i) an undoped layer, or (ii) a layer having a n-type impurity concentration lower than that of the first intermediate barrier layer.

19. The nitride semiconductor light-emitting element according to claim 18,
wherein the second intermediate barrier layer contains n-type impurities, and
wherein the n-type impurity concentration of the n-side first barrier layer is larger than a n-type impurity concentration of the second intermediate barrier layer.
